(19) United States
(12) Patent Application Publication
(10) Pub. No.: US 2025/0205789 A1
(43) Pub. Date: Jun. 26, 2025

(54) SURFACE-COATED CUTTING TOOL

(71) Applicant: MITSUBISHI MATERIALS CORPORATION, Tokyo (JP)

(72) Inventors: Sho TATSUOKA, Naka-shi (JP); Shunsuke TOJO, Naka-shi (JP)

(73) Assignee: MITSUBISHI MATERIALS CORPORATION, Tokyo (JP)

(21) Appl. No.: 18/852,365

(22) PCT Filed: Mar. 15, 2023
(86) PCT No.: PCT/JP2023/010052

§ 371 Date: Sep. 27, 2024

(30) Foreign Application Priority Data
Mar. 30, 2022 (JP) 2022-055518

(51) Int. Cl. B23B 27/14

(52) U.S. Cl. CPC B23B 27/148; B23B 2224/32; B23B 2228/105

(57) ABSTRACT

A surface coated cutting tool includes a substrate and a coating layer. The coating layer includes a complex carbonitride layer. The complex carbonitride layer has an average thickness of 1.0 μm or more and 20.0 μm or less. The complex carbonitride layer includes NaCl-type face-centered cubic crystal grains, each containing: metal components Ti, V, Zr, and Nb in atomic fractions a₁, a₂, a₃, and a₄, respectively, where the total atomic fraction of the metal components in the layer is 1; non-metallic components C and N in atomic fractions b₁ and b₂, respectively, where the total atomic fraction of the non-metallic components is 1; and inevitable impurities. The atomic fractions a₁, a₂, a₃, a₄, b₁, and b₂ satisfy the relations:

$$0.01 \leq {a}_{1} \leq 0.6 ,$$

$$0.01 \leq {a}_{2} \leq 0.6 ,$$

$$0.01 \leq {a}_{3} \leq 0.6 ,$$

$$0.01 \leq {a}_{4} \leq 0.6 ,$$

$$0.2 \leq {b}_{1} \leq 0.8 ,$$

$$and$$

$$0.2 \leq {b}_{2} \leq 0.8 .$$

### CROSS-REFERENCE TO RELATED PATENT APPLICATIONS

This application is a U.S. National Phase Application under 35 U.S.C. § 371 of International Patent Application No. PCT/JP2023/010052 filed on Mar. 15, 2023, which claims the benefit of priority to Japanese Patent Application No. 2022-55518 filed on Mar. 30, 2022, the contents of all of which are incorporated herein by reference in their entireties. The International Application was published in Japanese on Oct. 5, 2023 as International Publication No. WO2023/189595 under PCT Article 21(2).

### FIELD OF THE INVENTION

The present invention relates to surface coated cutting tools (hereinafter referred to as “coated tools”).

### BACKGROUND OF THE INVENTION

A coated tool is known including a substrate composed of tungsten carbide (hereinafter denoted by WC) based cemented carbide, for example, and a coating layer on the substrate. Such coated tools exhibit high wear resistance. Various proposals have also been made on improvements in coating layers in order to enhance the durability of coated tools.

For example, Japanese Patent No. 4028891 discloses a tool including a substrate and a coating layer on the substrate, in which the coating layer has a composition represented by (TiₓZr₁₋ₓ) (C_{y}N_{1-y}) (where 0.4<x<0.95, 0.2<y<0.9) having a face-centered cubic structure with a lattice constant of 0.403 to 0.455 nm or by (TiₓHf₁₋ₓ) (CyN_{1-y}) (where 0.4<x<0.95, 0.2<y<0.9) having a face-centered cubic structure with a lattice constant of 0.430 to 0.450 nm. Such a coating layer is hard and has high wear resistance.

US Patent Application Publication No. 2016/0298233 describes a coated tool (insert) including a substrate and a coating layer on the substrate, in which the coating layer is composed of fcc Ti₁₋ₓMeₓ nitride (0.1≤x≤0.9, Me being one or more of Zr and Hf) having a lattice constant of 0.427 to 0.453 nm. The coating layer of the coated tool is hard and suitable for dry cutting of stainless steel.

### CITATION LIST

### Patent Literature

PTL 1: Japanese Patent No. 4028891
PTL2: US Patent Application Publication No. 2016/0298233

### Technical Problem

An object of the present invention, which has been accomplished in view of the aforementioned circumstances and proposal, is to provide a coated tool having a coating layer with high hardness and improved toughness.

### SUMMARY OF THE INVENTION

### Solution to Problem

The surface coated cutting tool according to the embodiment of the present invention comprises:
a substrate and a coating layer on a surface of the substrate,
the coating layer comprising a complex carbonitride layer,
the complex carbonitride layer having an average thickness of 1.0 μm or more and 20.0 μm or less,
the complex carbonitride layer comprising NaCl-type face-centered cubic crystal grains each containing:
   metal components Ti, V, Zr, and Nb in atomic fractions a₁, a₂, a₃, and a₄, respectively, where the total atomic fraction of the metal components in the layer is 1;
   non-metallic components C and N in atomic fractions b₁ and b₂, respectively, where the total atomic fraction of the non-metallic components is 1; and
   inevitable impurities, wherein
the atomic fractions a₁, a₂, a₃, a₄, b₁, and b₂ satisfy the following relations:

$$0.01 \leq {a}_{1} \leq 0.6 ,$$

$$0.01 \leq {a}_{2} \leq 0.6 ,$$

$$0.01 \leq {a}_{3} \leq 0.6 ,$$

$$0.01 \leq {a}_{4} \leq 0.6 ,$$

$$0.2 \leq {b}_{1} \leq 0.8 ,$$

$$and$$

$$0.2 \leq {b}_{2} \leq 0.8 ,$$

the crystal grains each have a configuration parameter S_{config} expressed by Expression 1 of 0.80R or more,

$${S}_{config} = - \frac{R}{2} [ {\sum }_{i = 1}^{n} {a}_{i} ln ( {a}_{i} ) + {\sum }_{j = 1}^{m} {b}_{j} ln ( {b}_{j} ) ] \qquad ( 1 )$$

where n=4 and m=2, ln represents the natural logarithm, and R represents the gas constant.

The surface coated cutting tool of the above embodiment may satisfy at least one of the following items (1) and (2):

(1) The complex carbonitride layer further contains at least one metallic component selected from the group consisting of Hf and Ta in atomic fractions of as and a₆, respectively, wherein
the atomic fractions as and a₆ satisfy the following relations:
a₅<0.01, and
a₆<0.01, respectively,
the crystal grains each have a configuration parameter S_{config} expressed by Expression 1 of 0.80R or more,
   where n=6 and m=2, ln represents the natural logarithm, and R represents the gas constant, with the proviso that if a₁ (i=5 or 6) is zero (not contained), aᵢln(aᵢ)=0.
   (2) The complex carbonitride layer further contains 0.50 atomic percent or less of Cl.

### Advantageous Effects of Invention

The embodiment of the surface-coated cutting tool includes a coating layer having high hardness and high toughness.

### BRIEF DESCRIPTION OF THE DRAWINGS

FIG. 1 is a schematic diagram of the crystal structure of TiN.

FIG. 2 is a schematic diagram of the crystal structure of (TiVZrNb) (CN) or (TiVZrNbHfTa) (CN).

### DETAILED DESCRIPTION OF THE INVENTION

Since the hardness and toughness of the coating layer of a surface-coated cutting tool are in a trade-off relationship, it is believed to be difficult to achieve both by the conventional solid solution strengthening theory.

Meanwhile, research has recently been conducted on solid solutions with increased entropy of mixing, such as high-entropy alloys, which consist of five or more elements mixed in substantially equal atomic proportions, and multi principal element alloys, which consist of three or more elements containing at least two or more principal elements. No research, however, are found on increasing the entropy of mixing in the coating layer of coated tools.

The inventor has made an extensive study on the solid solution (alloy) that constitutes the coating layer of the coated tool to achieve compatibility between high hardness and high toughness through increasing the entropy of mixing, which have been in trade-off relation and have not been achieved in conventional coating layers.

As a result, the inventor found that an increase in entropy in the complex carbonitride layer of a specific composition which constitutes the coating layer of the coated tool leads to:
(i) formation of a complex carbonitride layer with a specific composition composed of several atoms with different atomic radii causing distortion in crystal grains and thus improving hardness and toughness; and
(ii) improvements in thermal stability and oxidation resistance of the complex carbonitride layer at high temperatures.

The surface-coated cutting tools of the present invention will now be described.

Throughout the specification and the claims, a numerical range expressed as “L to M” (L and M are both numerical values) is synonymous with “L or more and M or less,” and the range includes the upper limit (M) and the lower limit (L). In the case that units are stated only for the upper limit, the units for the upper (M) and lower (L) limits are the same.

### I. First Embodiment

The complex carbonitride of (TiVZrNb) (may also be denoted as (TiVZrNb) (CN)), which constitutes the coating layer of the first embodiment, will now be described.

### 1. Coating Layer

### 1-1. (TiVZrNb) (CN) Layer

### (1) Crystal Structure

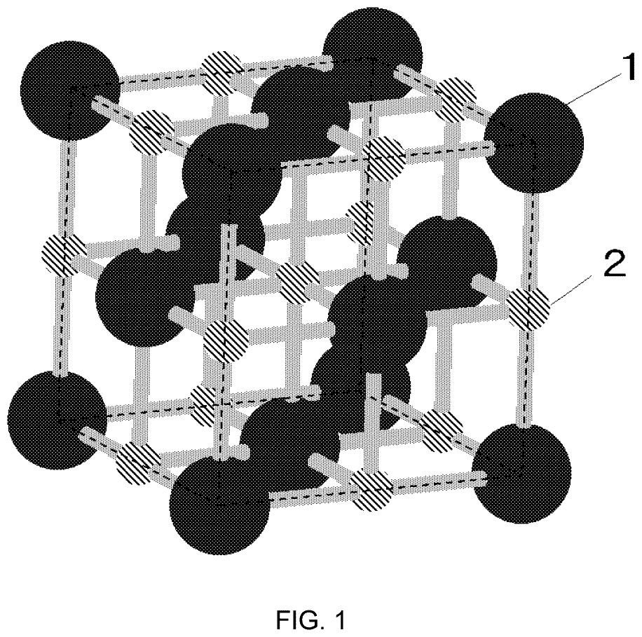

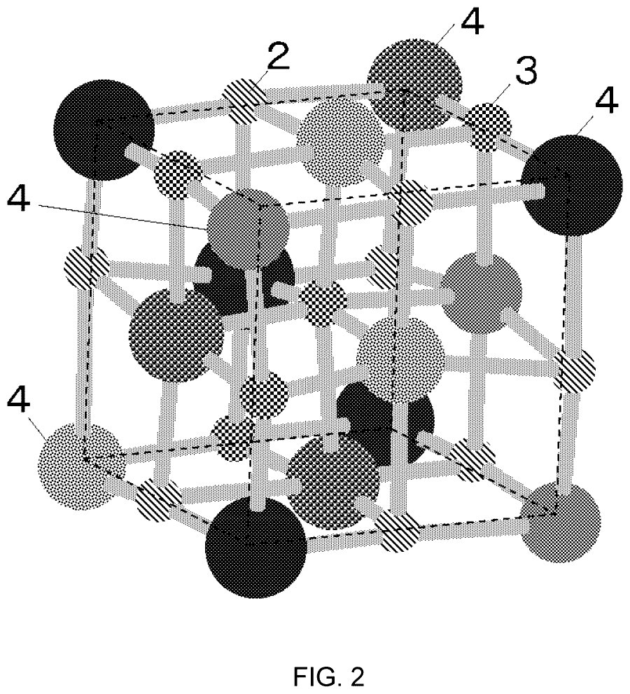

(TiVZrNb) (CN) has an atomic arrangement shown in FIG. 2. Ti, V, Zr, or Nb atoms, which have different atomic radii, are present in the cationic site (4), and C and N atoms are mixed at random or without regularity in the anionic sites (2 and 3), in a crystal lattice. Compared to the crystal structure of TiN (Ti atoms (1) and N atoms (2)) shown schematically in FIG. 1, each atom is displaced from the ideal lattice point in this crystal lattice. This causes strain in the crystal lattice (indicated by the displacement from the dotted line in FIG. 2), and this strain results in improved hardness and toughness. The extent of displacement of each atom is also shown schematically in FIG. 2.

### (2) Average Thickness

The average thickness of the (TiVZrNb) (CN) layer, which is a complex carbonitride layer, should preferably be 1.0 μm or more and 20.0 μm or less, for the following reasons: An average thickness of less than 1.0 μm, which is significantly small, leads to insufficient durability of the (TiVZrNb) (CN) layer. An average thickness exceeding 20.0 μm leads to ready formation of coarse crystal grains in the (TiVZrNb) (CN) layer, resulting in frequent chipping. The average thickness of the (TiVZrNb) (CN) layer should more preferably be 3.0 μm or more and 16.0 μm or less.

### (3) Composition

The (TiVZrNb) (CN) layer, which is a complex carbonitride layer, preferably has a composition represented by the chemical formula: (Tiₐ₁Vₐ₂Zrₐ₃Nbₐ₄) (C_{b1}N_{b2}), where the atomic fractions a₁, a₂, a₃, a₄, b₁, b₂ satisfy the following relations:

$${a}_{1} + {a}_{2} + {a}_{3} + {a}_{4} = 1$$

$$and$$

$${b}_{1} + {b}_{2} = 1 ;$$

$$0.01 \leq {a}_{1} \leq 0.6 ;$$

$$0.01 \leq {a}_{2} \leq 0.6 ;$$

$$0.01 \leq {a}_{3} \leq 0.6 ;$$

$$0.01 \leq {a}_{4} \leq 0.6 ;$$

$$0.2 \leq {b}_{1} \leq 0.8 ;$$

$$0.2 \leq {b}_{2} \leq 0.8 ;$$

the crystal grains in the layer each have a configuration parameter S_{config} expressed in Expression 1 is 0.80R or more
   where n=4 and m=2, ln represents the natural logarithm, and R represents the gas constant.

The layer may contain unintended or inevitable impurities that are introduced during the manufacturing process.

$${S}_{config} = - \frac{R}{2} [ {\sum }_{i = 1}^{n} {a}_{i} ln ( {a}_{i} ) + {\sum }_{j = 1}^{m} {b}_{j} ln ( {b}_{j} ) ] \qquad ( 1 )$$

The atomic fractions a₁, a₂, a₃, a₄, b₁ and b₂ satisfying the relations causes the entropy of mixing of the (TiVZrNb) (CN) layer to be enhanced, and the (TiVZrNb) (CN) layer to have the advantageous effects (i)-(ii) found by the inventor.

The atomic fractions a₁, a₂, a₃, a₄, b₁, and b₂ should preferably be determined such that the configuration parameter S_{config} has a larger value. The upper limit for the calculation of the configuration parameter S_{config} is 1.04R.

### (4) Cl Content

Cl is inevitably contained in a very trace amount (an amount the presence of which can only just be confirmed by analysis by single-element detection of chlorine only) in the layer deposited by the CVD process using a chloride raw material gas. A Cl content of 0.50 atomic percent or less causes a lubricant (TiVZrNb) (CN) layer to be formed due to the effect of Cl. The Cl content (atomic percent) is defined by the percentage to all atoms of Ti, V, Zr, Nb, C, N, and Cl.

### (5) NaCl-Type Face-Centered Cubic Structure

The (TiVZrNb) (CN) layer should preferably contain crystal grains with a NaCl-type face-centered cubic structure. The layer may also contain crystal grains other than the NaCl-type face-centered cubic structure, but the presence of crystal grains other than the NaCl-type face-centered cubic structure is not intended. Having crystal grains with a NaCl-type face-centered cubic structure in the claims and specification means that crystal grains other than this unintended NaCl-type face-centered cubic structure may be present in addition to crystal grains with a NaCl-type face-centered cubic structure.

### 1-2. Other Layers

### (1) Bottom Layer

A bottom layer may be disposed between the substrate and the (TiVZrNb) (CN) layer, where the bottom layer consists of one or more sublayers each composed of titanium nitride, titanium carbide, or titanium carbonitride (not limited to stoichiometric composition) with a total average thickness of 0.1 to 20.0 μm. The bottom layer improves the adhesion between the substrate and the (TiVZrNb) (CN) layer.

### (2) Top Layer

A top layer may be disposed on the (TiVZrNb) (CN) layer, where the top layer consists of one or more sublayers each composed of titanium nitride, titanium carbide, titanium carbonitride, titanium oxide and/or aluminum oxide (not limited to stoichiometric composition) with a total average thickness of 0.1 to 25.0 μm. The top layer improves chipping and wear resistance.

### (3) Unintentionally Generated Layers

If the pressure and/or temperature of the gas in the CVD furnace is unstable, a layer different from the (TiVZrNb) (CN) layer, bottom layer, and top layer may be deposited unintentionally.

### 2. Substrate

### (1) Material

The substrate may be of any known substrate material that does not hinder the achievement of the purpose of the invention. Examples of such a material include WC-based cemented carbides (containing carbides or nitrides of Co, Ti, Zr, Ta, Nb, and Cr, in addition to WC), cermets (mainly composed of TiC, TiN, and TiCN), ceramics (titanium carbide, silicon carbide, silicon nitride, aluminum nitride, and aluminum oxide), and cBN compacts.

### (2) Shape

The substrate may have any shape suitable for use in a cutting tool, for example, shapes of an insert and a solid tool.

### 3. Measurement

The average thickness, the contents of individual elements, and the average chlorine content of the (TiVZrNb) (CN) layer are determined as follows:

### (1) Average Thickness

The average thickness of the (TiVZrNb) (CN) layer can be determined as follows: A sample for observation of the longitudinal section of the coating layer is prepared with a cross-section polisher (CP) or any other instrument, the longitudinal section is observed with a scanning electron microscope (SEM), and then the thickness of the layer is measured at several sites (e.g., at five sites). The thicknesses at several sites are averaged into the average thickness of the (TiVZrNb) (CN) layer. The definition of the surface of the substrate will be described below.

The longitudinal section indicates a cross-section perpendicular to a surface (regarded as a flat surface without irregularities) of the substrate in the case of the insert.

The surface of the substrate is defined by the average line (straight line) of the rough interface between the substrate and the coating layer in the observed image of the longitudinal section.

The interface between the (TiVZrNb) (CN) coating layer (or the bottom layer if present) and the substrate is determined from the observed image of the longitudinal section described above. The average line of the roughness curve of the interface is defined as the surface of the substrate. The direction perpendicular to the average line is the direction perpendicular to the substrate (thickness direction of the layer).

In the case that the radius of curvature of the curved surface is sufficiently large relative to the thickness of the coating layer in the substrate having a curved surface, the interface between the coating layer and the substrate in the observation area is regarded as a plane surface; hence, the surface of the substrate can be determined by the same procedure.

### (2) Contents of Individual Elements and Chlorine in the Coating Layer

The contents of individual elements and chlorine in the (TiVZrNb) (CN) layer are determined as follows:

The Ti content a₁, V content a₂, Zr content a₃, Nb content a₄, the C content b₁, the N content b₂, and chlorine content are the averages of the results of characteristic X-ray analysis observed at ten points by irradiation of the polished surface of the sample of the coating layer with electron beams using an electron probe micro analyzer (EPMA).

### (3) Identification of the Crystal Structure in the (TiVZrNb) (CN) Layer

The (TiVZrNb) (CN) layer is subjected to X-ray diffractometry to confirm that the layer has a NaCl-type face-centered cubic structure. The X-ray diffraction is measured by the 2θ-θ method using CuKα rays, under the following conditions: scanning range (2θ) of 15 to 135 degrees, X-ray output of 45 kV and 40 mA, divergence slit of 0.5 degrees, and scan step of 0.013 degrees.

### 4. Production

The (TiVZrNb) (CN) layer can be produced by a CVD process using, for example, TiCl₄, ZrCl₄, VCl₄, NbCl₅, HCl, N₂, CH₃CN, Ar, and H₂ gases.

### II. Second Embodiment

The complex carbonitride of (TiVZrNbHfTa) (sometimes denoted as (TiVZrNbHfTa) (CN)), which constitutes the coating layer of the second embodiment, will now be described.

### 1. Coating Layer

### 1-1. (TiVZrNbHfTa) (CN) Layer

### (1) Crystal Structure

The crystal structure is the one in which “(TiVZrNbHfTa) (CN)” and “Ti, V, Zr, Nb, Hf, Ta atoms (Hf and Ta are selected depending on the composition)” are substituted for “(TiVZrNb) (CN)” and “Ti, V, Zr, Nb atoms” respectively in the description of the first embodiment for the crystal structure.

### (2) Average Thickness

The average thickness is the replacement of “(TiVZrNb)” with “(TiVZrNbHfTa)” in the description of the first embodiment regarding average thickness.

### (3) Composition

The (TiVZrNbHfTa) (CN) layer, which is a complex carbonitride layer, preferably has a composition represented by the chemical formula: (Tiₐ₁Vₐ₂Zrₐ₃Nbₐ₄Hfₐ₅Taₐ₆) (C_{b1}N_{b2}), where the atomic fractions a₁, a₂, a₃, a₄, a₅, a₆, b₁, b₂ satisfy the following relations:

$${a}_{1} + {a}_{2} + {a}_{3} + {a}_{4} + {a}_{5} + {a}_{6} = 1$$

$$and$$

$${b}_{1} + {b}_{2} = 1 ;$$

$$0.01 \leq {a}_{1} \leq 0.6 ;$$

$$0.01 \leq {a}_{2} \leq 0.6 ;$$

$$0.01 \leq {a}_{3} \leq 0.6 ;$$

$$0.01 \leq {a}_{4} \leq 0.6 ;$$

$$0. \leq {a}_{5} \leq 0.01 ;$$

$$0. \leq {a}_{6} \leq 0.01 ;$$

$$0.2 \leq {b}_{1} \leq 0.8 ;$$

$$0.2 \leq {b}_{2} \leq 0.8 ;$$

and
the crystal grains in the layer each have a configuration parameter S_{config} expressed in Expression 1 is 0.80R or more
   where n=6 and m=2, ln represents the natural logarithm, and R represents the gas constant.

The layer may contain unintended or inevitable impurities that are introduced during the manufacturing process.

$${S}_{config} = - \frac{R}{2} [ {\sum }_{i = 1}^{n} {a}_{i} ln ( {a}_{i} ) + {\sum }_{j = 1}^{m} {b}_{j} ln ( {b}_{j} ) ] \qquad ( 1 )$$

At aᵢ (i=5 or 6) of 0.00 (in the case that Hf or Ta is not contained), aᵢln(a₁) is regarded as 0 (zero).

The atomic fractions a₁, a₂, a₃, a₄, a₅, a₆, b₁ and b₂ satisfying the relations causes the entropy of mixing of the (TiVZrNbHfTa) (CN) layer to be enhanced, and the (TiVZrNbHfTa) (CN) layer to have the advantageous effects (i)-(ii) found by the inventor.

The atomic fractions a₁, a₂, a₃, a₄, a₅, a₆, b₁ and b₂ should preferably be determined such that the configuration parameter S_{config} has a larger value. Since the upper limits of atomic fractions a₅ and a₆ are both less than 0.01, the upper limit for the calculation of the configuration parameter S_{config} is 1.08R.

### (4) Cl Content

The Cl content is the replacement of “(TiVZrNb) (CN)” with “(TiVZrNbHfTa) (CN)” in the description of the first embodiment for the Cl content. The Cl content (atomic percent) is defined by the percentage of all atoms of Ti, V, Zr, Nb, Hf, Ta, C, N, and Cl.

(5) NaCl-type face-centered cubic structure

Regarding the NaCl-type face-centered cubic structure, “(TiVZrNb)” is replaced with “(TiVZrNbHfTa)” in the description of the first embodiment for NaCl-type face-centered cubic structure above.

### 1-2. Other Layers

Regarding the other layers, “(TiVZrNb)” is replaced with “(TiVZrNbHfTa)” in the description of the first embodiment for the other layers.

### 2. Substrate

The substrate is the same as described in the first embodiment.

### 3. Measurement

Regarding the measurement, “(TiVZrNb)” is replaced with “(TiVZrNbHfTa)” in the description on the measurement of the first embodiment. The contents of Hf and Ta are also measured by EPMA.

### 4. Production

The (TiVZrNbHfTa) (CN) layer of this embodiment can be produced by CVD with, for example, deposition gases containing HfCl₄ and TaCl₅ in addition to TiCl₄, ZrCl₄, VCl₄, NbCl₅, HfCl₄, TaCl₅, HCl, N₂, CH₃CN, Ar and H₂ used in the first embodiment.

The above description supports the following Appendices:

### Appendix 1

A surface coated cutting tool comprising:
a substrate and a coating layer on a surface of the substrate,
the coating layer comprising a complex carbonitride layer,
the complex carbonitride layer having an average thickness of 1.0 μm or more and 20.0 μm or less,
the complex carbonitride layer comprising NaCl-type face-centered cubic crystal grains each containing:
   metal components Ti, V, Zr, and Nb in atomic fractions a₁, a₂, a₃, and a₄, respectively, where the total atomic fraction of the metal components in the layer is 1;
   non-metallic components C and N in atomic fractions b₁ and b₂, respectively, where the total atomic fraction of the non-metallic components is 1; and
   inevitable impurities, wherein
the atomic fractions a₁, a₂, a₃, a₄, b₁, and b₂ satisfy the following relations:

$$0.01 \leq {a}_{1} \leq 0.6 ,$$

$$0.01 \leq {a}_{2} \leq 0.6 ,$$

$$0.01 \leq {a}_{3} \leq 0.6 ,$$

$$0.01 \leq {a}_{4} \leq 0.6 ,$$

$$0.2 \leq {b}_{1} \leq 0.8 ,$$

$$and$$

$$0.2 \leq {b}_{2} \leq 0.8 ,$$

the crystal grains each have a configuration parameter S_{config} expressed by Expression 1 of 0.80R or more

$${S}_{config} = - \frac{R}{2} [ {\sum }_{i = 1}^{n} {a}_{i} ln ( {a}_{i} ) + {\sum }_{j = 1}^{m} {b}_{j} ln ( {b}_{j} ) ] \qquad ( 1 )$$

where n=4 and m=2, ln represents the natural logarithm, and R represents the gas constant.

### Appendix 2

The surface coated cutting tool set forth in Appendix 1, wherein the complex carbonitride layer further contains at least one metallic component selected from the group consisting of Hf and Ta in atomic fractions of as and a₆, respectively, wherein
the atomic fractions as and a₆ satisfy the following relations:
a₅<0.01, and
a_{6<0.01}, respectively,
the crystal grains each have a configuration parameter S_{config} expressed by Expression 1 of 0.80R or more, where n=6 and m=2, ln represents the natural logarithm, and R represents the gas constant, with the proviso that if aᵢ (i=5 or 6) is zero (not contained), aᵢln(a)=0.

### Appendix 3

The surface coated cutting tool set forth in Appendix 1 or 2, wherein the complex carbonitride layer further contains 0.50 atomic percent or less of Cl.

### Appendix 4

The surface coated cutting tool set forth in any of Appendices 1 to 3, further comprising a bottom layer between the substrate and the complex carbonitride layer, the bottom layer including at least one sublayer composed of titanium nitride, titanium carbide, or titanium carbonitride and having a total average thickness of 0.1 to 20.0 μm.

### Appendix 5

The surface coated cutting tool set forth in any of Appendices 1 to 4, further comprising a top layer on the complex carbonitride layer, the top layer including at least one sublayer composed of titanium nitride, titanium carbide, titanium carbonitride, or titanium oxide layer and having a total average thickness of 0.1 to 25.0 μm.

### EXAMPLES

The present invention will now be described by way of Examples. The present invention should not be limited to Examples. Examples show insert cutting tools including substrates made of WC-based cemented carbide, but the substrate may be composed of any of the aforementioned materials, and the cutting tool may have any other shape, such as a solid tool, as described above.

### Examples of First Embodiment

### 1. Production of Substrate

WC, TiC, ZrC, TaC, NbC, Cr₃C₂, TiN, and Co raw powders were blended into compositions shown in Table 1, and then were ball-milled together with wax in acetone for 24 hours. After being dried under reduced pressure, each mixture was pressed into a green compact of a predetermined shape under a pressure of 98 MPa.

The green compact was then sintered under vacuum, and then the cutting edges of the sinter were honed to R of 0.05 mm. WC-based cemented carbide substrates A through C, each with an insert shape of CNMG120408-MA manufactured by Mitsubishi Materials Corporation were thereby produced.

### 2. Deposition

(TiVZrNb) (CN) layers were deposited on the surfaces of substrates A to C in a CVD system to yield Examples 1 to 10 shown in Table 5. The conditions for deposition were as shown in Table 2, and were generally as follows:

Composition of reaction gas (content of gas component is in volume %):
TiCl₄: 0.02 to 0.10%
ZrCl₄: 0.10 to 0.50%.
VCl₄: 0.02 to 0.10%
NbCl₅: 0.02 to 0.10%
CH₃CN: 0.10 to 0.50%,
HCl: 0.10 to 0.50%,
N₂: 0.0 to 12.0%,
Ar: 10.0 to 50.0%, and
H₂: balance
Pressure of reaction atmosphere: 4.5 to 12.0 kPa
Temperature of reaction atmosphere: 800 to 950° C.

In Examples 3 to 10, the bottom layer(s) and/or top layer(s) shown in Table 4 were deposited under the conditions shown in Table 3.

For comparison, (TiVZrNb) (CN) layers were deposited on the surfaces of substrates A to C according to the conditions of deposition shown in Table 2 to yield Comparative Examples 1 to 10 shown in Table 5. For the production of the comparative examples, the composition of the raw material gases was varied from those of Examples. For comparative examples 3 to 10, the bottom layer(s) and/or the top layer(s) shown in Table 4 were deposited according to the conditions shown in Table 3.

To contrast the present invention with the conventional technology, a TiCN layer was deposited on the surface of substrate A and C under the conditions shown in Table 3 and a bottom sublayer shown in Table 4 was deposited to produce Conventional Example 1 shown in Table 5, or a bottom sublayer and top sublayers shown in Table 4 were deposited to produce Conventional Example 2 also shown in Table 5.

The average thickness of each layer, and the content of each element and the chlorine content in each layer were measured, and the NaCl-type face-centered cubic structure in each layer was identified for Examples 1 to 10, Comparative Examples 1 to 10, and Conventional Examples 1 to 2, by the methods described above.

The results are summarized in Table 5.

TABLE 1

| | | Composition (mass %) | | | | | | | |
|---|---|---|---|---|---|---|---|---|---|
| Type | | Co | TiC | ZrC | TaC | NbC | Cr₃C₂ | TiN | WC |
| Substrate | A | 6.1 | 0.0 | 1.5 | 0.5 | 2.8 | 0.1 | 1.5 | Balance |
| | B | 7.2 | 2.5 | 0.0 | 3.2 | 0.4 | 0.0 | 1.1 | Balance |
| | C | 5.5 | 0.0 | 0.0 | 0.0 | 0.0 | 0.0 | 0.0 | Balance |

TABLE 2

| | | Formation of (TiVZrNb) (CN) layer | | | | | | | | | | |
|---|---|---|---|---|---|---|---|---|---|---|---|---|
| | | | | | | | | | | | Reaction | |
| | | | | | | | | | | | atmosphere | |
| Type of | | | | | | | | | | | Pres- | |
| deposition | | Composition of reaction gas (volume %) | | | | | | | | | sure | Temp. |
| process | Symbol | TiCl₄ | VCl₄ | ZrCl₄ | NbCl₅ | CH₃CN | HCl | N₂ | Ar | H₂ | (kPa) | (° C.) |
| Process | A | 0.10 | 0.10 | 0.10 | 0.10 | 0.30 | 0.30 | 0.0 | 35.0 | Balance | 4.5 | 900 |
| of | B | 0.05 | 0.05 | 0.30 | 0.05 | 0.30 | 0.50 | 5.0 | 50.0 | Balance | 12.0 | 800 |
| Examples | C | 0.02 | 0.05 | 0.30 | 0.02 | 0.50 | 0.30 | 0.0 | 10.0 | Balance | 7.0 | 950 |
| | D | 0.05 | 0.07 | 0.50 | 0.07 | 0.10 | 0.10 | 12.0 | 35.0 | Balance | 7.0 | 900 |
| | E | 0.07 | 0.10 | 0.50 | 0.05 | 0.10 | 0.30 | 0.0 | 25.0 | Balance | 4.5 | 950 |
| | F | 0.05 | 0.07 | 0.30 | 0.05 | 0.30 | 0.50 | 0.0 | 25.0 | Balance | 4.5 | 900 |
| | G | 0.10 | 0.07 | 0.20 | 0.05 | 0.30 | 0.30 | 2.0 | 25.0 | Balance | 7.0 | 900 |
| | H | 0.07 | 0.02 | 0.30 | 0.07 | 0.30 | 0.50 | 5.0 | 35.0 | Balance | 12.0 | 950 |
| | I | 0.07 | 0.05 | 0.10 | 0.10 | 0.30 | 0.10 | 12.0 | 50.0 | Balance | 4.5 | 800 |
| | J | 0.05 | 0.05 | 0.20 | 0.07 | 0.30 | 0.50 | 2.0 | 10.0 | Balance | 7.0 | 950 |
| Process | A′ | 0.07 | 0.01 | 0.70 | 0.20 | 0.30 | 0.50 | 12.0 | 50.0 | Balance | 4.5 | 950 |
| of | B′ | 0.01 | 0.07 | 0.05 | 0.25 | 0.30 | 0.10 | 2.0 | 35.0 | Balance | 7.0 | 900 |
| Comparative | C′ | 0.03 | 0.01 | 0.60 | 0.01 | 0.30 | 0.50 | 2.0 | 35.0 | Balance | 4.5 | 800 |
| Examples | D′ | 0.01 | 0.01 | 0.03 | 0.07 | 0.30 | 0.30 | 0.0 | 35.0 | Balance | 12.0 | 950 |
| | E′ | 0.28 | 0.02 | 0.10 | 0.25 | 0.30 | 0.30 | 0.0 | 10.0 | Balance | 7.0 | 950 |
| | F′ | 0.01 | 0.20 | 0.80 | 0.01 | 0.30 | 0.50 | 12.0 | 25.0 | Balance | 12.0 | 950 |
| | G′ | 0.30 | 0.02 | 0.50 | 0.02 | 0.50 | 0.10 | 5.0 | 25.0 | Balance | 7.0 | 800 |
| | H′ | 0.10 | 0.30 | 0.05 | 0.01 | 0.30 | 0.30 | 0.0 | 50.0 | Balance | 4.5 | 900 |
| | I′ | 0.05 | 0.25 | 0.10 | 0.02 | 0.10 | 0.30 | 0.0 | 25.0 | Balance | 7.0 | 900 |
| | J′ | 0.02 | 0.02 | 0.10 | 0.15 | 0.10 | 0.50 | 5.0 | 10.0 | Balance | 4.5 | 900 |

TABLE 3

| | | Conditions of deposition (Pressure and temperature of | | |
|---|---|---|---|---|
| Sublayer Constituting | | reaction atmosphere are shown in kPa and ° C., respectively.) | | |
| coating layer | | | Reaction atmosphere | |
| Type | | Composition of reaction gas (volume %) | Pressure | Temperature |
| Ti compound layer | TiN | TiCl₄: 4.2%, N₂: 30%, H₂: Balance | 7.0 | 900 |
| | TiCN | TiCl₄: 2%, CH₃CN: 0.7%, N₂: 10%, H₂: Balance | 7.0 | 900 |
| | TiCNO | TiCl₄: 2%, CH₃CN: 0.7%, CO: 1%, N₂: 10%, H₂: Balance | 7.0 | 1000 |
| Al₂O₃ layer | Al₂O₃ | AlCl₃: 2.2%, CO₂: 5.5%, HCl: 2.2%, H₂S: 0.2%, H₂: Balance | 7.0 | 1000 |

TABLE 4

| | | | Coating layer | | | |
|---|---|---|---|---|---|---|
| | | | (Lower number indicates average | | | |
| | | | thickness (μm) of layer.) | | | |
| | | | Bottom layer (s) | | Top layer (s) | |
| | | Substrate | First | Second | First | Second |
| Type | | symbol | sublayer | sublayer | sublayer | sublayer |
| Examples | 3 | C | TiN | — | — | — |
| & | | | (0.3) | | | |
| Comparative | 4 | A | TiN | — | TiCNO | Al₂O₃ |
| Examples | | | (0.1) | | (0.8) | (3.2) |
| | 5 | B | TiN | TiCN | TiCNO | Al₂O₃ |
| | | | (0.3) | (2.2) | (0.3) | (8.1) |
| | 6 | C | TiN | TiCN | — | — |
| | | | (1.5) | (3.7) | | |
| | 7 | A | — | — | Al₂O₃ | — |
| | | | | | (6.3) | |
| | 8 | B | TiN | TiCN | TiCNO | Al₂O₃ |
| | | | (1.0) | (3.2) | (0.2) | (4.2) |
| | 9 | C | TiN | TiCN | Al₂O₃ | — |
| | | | (0.4) | (2.0) | (3.4) | |
| | 10 | A | TiN | TiCN | TiCNO | Al₂O₃ |
| | | | (0.3) | (3.8) | (0.2) | (5.7) |
| Conventional | 1 | C | TiN | — | — | — |
| Examples | | | (0.2) | | | |
| | 2 | A | TiN | — | TiCNO | Al₂O₃ |
| | | | (0.2) | | (0.6) | (3.5) |

TABLE 5

| | | | Symbol | | | | | | | | Cl | Average |
|---|---|---|---|---|---|---|---|---|---|---|---|---|
| | | | of | Content | | | | | | | content | thickness |
| Type | | Substrate | deposition | a₁ | a₂ | a₃ | a₄ | b₁ | b₂ | S_{config}/R | (atomic %) | (μm) |
| Examples | 1 | A | A | 0.29 | 0.05 | 0.31 | 0.35 | 0.59 | 0.41 | 0.96 | 0.02 | 5.5 |
| | 2 | B | B | 0.19 | 0.25 | 0.14 | 0.42 | 0.41 | 0.59 | 0.99 | 0.05 | 7.1 |
| | 3 | C | C | 0.10 | 0.38 | 0.27 | 0.25 | 0.51 | 0.49 | 1.00 | 0.06 | 4.1 |
| | 4 | A | D | 0.15 | 0.30 | 0.20 | 0.35 | 0.20 | 0.80 | 0.92 | 0.02 | 7.3 |
| | 5 | B | E | 0.18 | 0.23 | 0.23 | 0.36 | 0.59 | 0.41 | 1.01 | 0.36 | 3.2 |
| | 6 | C | F | 0.17 | 0.22 | 0.30 | 0.31 | 0.65 | 0.35 | 1.00 | ** | 10.4 |
| | 7 | A | G | 0.38 | 0.13 | 0.22 | 0.27 | 0.30 | 0.70 | 0.97 | 0.30 | 8.5 |
| | 8 | B | H | 0.29 | 0.23 | 0.07 | 0.41 | 0.33 | 0.67 | 0.94 | 0.06 | 1.0 |
| | 9 | C | I | 0.27 | 0.02 | 0.20 | 0.51 | 0.20 | 0.80 | 0.80 | ** | 20.0 |
| | 10 | A | J | 0.19 | 0.18 | 0.18 | 0.45 | 0.35 | 0.65 | 0.97 | 0.04 | 6.5 |
| Comparative | 1 | A | A′ | 0.14 | 0.29 | 0.02 | 0.55 | 0.10 | 0.90 | 0.68 | 0.22 | 5.4 |
| Examples | 2 | B | B′ | 0.01 | 0.02 | 0.19 | 0.78 | 0.52 | 0.48 | 0.66 | 0.03 | 6.7 |
| | 3 | C | C′ | 0.16 | 0.66 | 0.01 | 0.17 | 0.38 | 0.62 | 0.79 | 0.08 | 4.6 |
| | 4 | A | D′ | 0.08 | 0.01 | 0.09 | 0.82 | 0.48 | 0.52 | 0.66 | ** | 7.0 |
| | 5 | B | E′ | 0.46 | 0.03 | 0.01 | 0.50 | 0.50 | 0.50 | 0.77 | ** | 2.8 |
| | 6 | C | F′ | 0.01 | 0.33 | 0.59 | 0.07 | 0.39 | 0.61 | 0.79 | 0.05 | 10.5 |
| | 7 | A | G′ | 0.67 | 0.19 | 0.01 | 0.13 | 0.45 | 0.55 | 0.79 | 0.46 | 7.6 |
| | 8 | B | H′ | 0.20 | 0.01 | 0.76 | 0.03 | 0.66 | 0.34 | 0.66 | 0.03 | 1.2 |
| | 9 | C | I′ | 0.11 | 0.01 | 0.70 | 0.18 | 0.59 | 0.41 | 0.76 | 0.04 | 19.6 |
| | 10 | A | J′ | 0.09 | 0.09 | 0.06 | 0.76 | 0.37 | 0.63 | 0.73 | 0.11 | 6.2 |
| Conventional | 1 | C | I′ | 1.00 | 0.00 | 0.00 | 0.00 | 0.62 | 0.38 | 0.33* | 0.04 | 4.9 |
| Examples | 2 | A | J′ | 1.00 | 0.00 | 0.00 | 0.00 | 0.63 | 0.37 | 0.33* | 0.04 | 7.6 |

In Table 5, the configuration parameter S_{config} is calculated from the expression —R/2[b₁ln(b₁)+b₂ln(b₂)] because Conventional Examples 1-2 do not contain V, Zr, and Nb.

The symbol “**” indicates that the content was below the quantitative limit of the analyzer. In this case, a peak assign to chlorine in the characteristic X-ray spectrum was observed by single-element detection of chlorine only, which results confirm that chlorine was contained in trace amounts.

It was also confirmed that all of Examples, Comparative Examples, and Conventional Examples have crystal grains with a substantially NaCl-type face-centered cubic structure.

While each of Examples 1 to 10, Comparative Examples 1 to 10, and Conventional Examples 1 to 2 was screwed to the tip of a tool steel bite with a fixture, wet end face cutting tests were conducted on a hollow round bar of alloy steel SCM440 with two evenly spaced grooves to measure the flank wear width of the cutting edge.

This cutting test is a process in which flank wear readily progresses and the cutting edge is prone to chipping due to intermittent machining. Since this machining requires both wear resistance and chipping resistance, the test is suitable for the evaluation of hardness and toughness.

### Cutting Test

Workpiece Material: JIS SCM440
   Hollow Round Bar with Two Evenly Spaced Grooves (20 mm Wide)
(Outer diameter: Φ180, inner diameter: Φ50)
Cutting speed: 250 m/min
Depth of cut: 1.5 mm
Feed rate: 0.4 mm/rev
Number of cutting operations: 20 passes

Table 6 shows the results of the cutting test. For Comparative Examples 1 to 10 and Conventional Examples 1 to 2, the number of cutting passes to the end of the life is shown because the tool reached the life before the number of cutting operations reached 20 passes due to chipping or flank wear (criterion of life determination: flank wear width 0.4 mm).

TABLE 6

| | | | | | Number | | | Number |
|---|---|---|---|---|---|---|---|---|
| | | Width | | | of | | | of |
| | | of | | | cutting | | | cutting |
| | | flank | | | passes to | | | passes to |
| | | wear | | | reach | | | reach |
| Type | | (mm) | Type | | lifetime | Type | | lifetime |
| Exam- | 1 | 0.16 | Com- | 1 | 15 | Conventional | 1 | 8 |
| ples | 2 | 0.27 | parative | 2 | 14 | Examples | 2 | 9 |
| | 3 | 0.17 | Examples | 3 | 9 | | | |
| | 4 | 0.18 | | 4 | 5 | | | |
| | 5 | 0.21 | | 5 | 16 | | | |
| | 6 | 0.16 | | 6 | 8 | | | |
| | 7 | 0.25 | | 7 | 10 | | | |
| | 8 | 0.26 | | 8 | 18 | | | |
| | 9 | 0.23 | | 9 | 16 | | | |
| | 10 | 0.27 | | 10 | 10 | | | |

As the results shown in Table 6 indicate that Examples 1 through 10 all exhibited low wear, no chipping, improved hardness and toughness, and thus excellent cutting performance over a long period of time.

In contrast, Comparative Examples 1 through 10 and Conventional Examples 1 and 2 each exhibited a large amount of wear or chipping and reached the end of its service life within a short time.

### Examples of Second Embodiment

### 1. Production of Substrate

Substrates A to C made of WC-based cemented carbide with the same insert geometry of CNMG120408-MA manufactured by Mitsubishi Materials as in the first embodiment were produced.

### 2. Deposition

(TiVZrNbHfTa) (CN) layers were deposited on the surfaces of substrates A to C in a CVD system to yield Examples 11 to 15 shown in Table 9. The conditions for deposition were as shown in Table 7, and were generally as follows:

Composition of reaction gas (content of gas component is in volume %):
TiCl₄: 0.02 to 0.10%
VCl₄: 0.02 to 0.10%
ZrCl₄: 0.10 to 0.50%
NbCl₅: 0.02 to 0.10%
*HfCl₄: 0.00 to 0.02%
*TaCl₅: 0.00 to 0.01%
CH₃CN: 0.10 to 0.50%
HCl: 0.10 to 0.50%
N₂: 0.0 to 12.0%
Ar: 10.0 to 50.0%
H₂: balance
*HfCl₄ and TaCl₅ are selected depending on the composition of the (TiVZrNbHfTa) (CN) layer.
Pressure of reaction atmosphere: 4.5 to 12.0 kPa
Temperature of reaction atmosphere: 800 to 950° C.

For each of Examples 13 to 15, the bottom layer(s) and/or the top layer(s) shown in Table 8 were deposited under the conditions shown in Table 3.

For comparison, (TiVZrNbHfTa) (CN) layers were deposited on the surfaces of Substrates A to C according to the conditions for deposition shown in Table 7 to yield Comparative Examples 11 to 15 shown in Table 9. In the process of the comparative examples, the composition of the raw material gases was different from those of the examples. For Comparative Examples 13 to 15, the bottom layer(s) and/or the top layer(s) shown in Table 8 were deposited under the conditions shown in Table 3.

The average thickness of each layer, and the content of each element and the chlorine content in each layer were measured, and the NaCl-type face-centered cubic structure in each layer was identified for Examples 11 to 15 and Comparative Examples 11 to 15, by the methods described above.

The results are summarized in Table 9.

TABLE 7

| | | Deposition of (TiVZrNbHfTa) (CN) layer | | | | | | | | | | | | |
|---|---|---|---|---|---|---|---|---|---|---|---|---|---|---|
| | | | | | | | | | | | | | Reaction | |
| Type | Symbol | | | | | | | | | | | | atmosphere | |
| of | of | Composition of reaction gas (volume %) | | | | | | | | | | | Pressure Temp. | |
| deposition | deposition | TiCl₄ | VCl₄ | ZrCl₄ | NbCl₅ | HfCl₄ | TaCl₅ | CH₃CN | HCl | N₂ | Ar | H₂ | (kPa) | (° C.) |
| Step | K | 0.07 | 0.02 | 0.30 | 0.07 | 0.01 | 0.01 | 0.30 | 0.50 | 5.0 | 35.0 | Balance | 12.0 | 950 |
| of | L | 0.05 | 0.05 | 0.30 | 0.05 | 0.02 | 0.00 | 0.30 | 0.50 | 5.0 | 50.0 | Balance | 12.0 | 800 |
| Examples | M | 0.07 | 0.05 | 0.10 | 0.10 | 0.00 | 0.01 | 0.30 | 0.10 | 12.0 | 50.0 | Balance | 4.5 | 800 |
| | N | 0.10 | 0.10 | 0.50 | 0.05 | 0.01 | 0.00 | 0.10 | 0.30 | 0.0 | 25.0 | Balance | 4.5 | 950 |
| | O | 0.02 | 0.05 | 0.30 | 0.02 | 0.00 | 0.01 | 0.50 | 0.30 | 0.0 | 10.0 | Balance | 7.0 | 950 |
| Step | K′ | 0.10 | 0.30 | 0.05 | 0.01 | 0.01 | 0.01 | 0.30 | 0.30 | 0.0 | 50.0 | Balance | 4.5 | 900 |
| of | L′ | 0.01 | 0.07 | 0.05 | 0.25 | 0.02 | 0.00 | 0.30 | 0.10 | 2.0 | 35.0 | Balance | 7.0 | 900 |
| Comparative | M′ | 0.05 | 0.25 | 0.10 | 0.02 | 0.00 | 0.01 | 0.10 | 0.30 | 0.0 | 25.0 | Balance | 7.0 | 900 |
| Examples | N′ | 0.28 | 0.02 | 0.10 | 0.25 | 0.01 | 0.00 | 0.30 | 0.30 | 0.0 | 10.0 | Balance | 7.0 | 950 |
| | O′ | 0.03 | 0.01 | 0.60 | 0.01 | 0.00 | 0.01 | 0.30 | 0.50 | 2.0 | 35.0 | Balance | 4.5 | 800 |

TABLE 8

| | | | Coating layer | | | |
|---|---|---|---|---|---|---|
| | | | (Lower number indicates average | | | |
| | | | thickness (μm) of layer.) | | | |
| | | | Bottom layer (s) | | Top layer (s) | |
| | | Substrate | First | Second | First | Second |
| Type | | symbol | sublayer | sublayer | sublayer | sublayer |
| Examples | 13 | C | TiN | — | — | — |
| & Comparative | | | (0.5) | | | |
| Examples | 14 | A | TiN | TiCN | TiCNO | Al₂O₃ |
| | | | (1.0) | (3.5) | (0.4) | (4.5) |
| | 15 | B | TiN | — | TiCNO | Al₂O₃ |
| | | | (0.3) | | (0.5) | (3.0) |

TABLE 9

| | | | Symbol | | | | | | | | | | | Average |
|---|---|---|---|---|---|---|---|---|---|---|---|---|---|---|
| | | | of | Content | | | | | | | | | Cl content | thickness |
| Type | | Substrate | deposition | a₁ | a₂ | a₃ | a₄ | a₅ | a₆ | b₁ | b₂ | S_{config}/R | (atomic %) | (μm) |
| Examples | 11 | A | K | 0.292 | 0.231 | 0.076 | 0.394 | 0.003 | 0.004 | 0.32 | 0.68 | 0.96 | 0.09 | 3.8 |
| | 12 | B | L | 0.197 | 0.242 | 0.135 | 0.421 | 0.005 | 0.000 | 0.44 | 0.56 | 1.01 | 0.06 | 6.7 |
| | 13 | C | M | 0.270 | 0.021 | 0.211 | 0.494 | 0.000 | 0.004 | 0.22 | 0.78 | 0.83 | ** | 12.4 |
| | 14 | A | N | 0.223 | 0.228 | 0.235 | 0.312 | 0.002 | 0.000 | 0.55 | 0.45 | 1.04 | 0.27 | 5.7 |
| | 15 | B | O | 0.103 | 0.384 | 0.261 | 0.244 | 0.000 | 0.008 | 0.49 | 0.51 | 1.01 | 0.08 | 4.5 |
| Comparative | 11 | A | K′ | 0.203 | 0.010 | 0.758 | 0.022 | 0.002 | 0.005 | 0.63 | 0.37 | 0.68 | 0.07 | 4.1 |
| Examples | 12 | B | L′ | 0.012 | 0.024 | 0.188 | 0.772 | 0.004 | 0.000 | 0.55 | 0.45 | 0.68 | 0.05 | 6.9 |
| | 13 | C | M′ | 0.113 | 0.012\| | 0.689 | 0.181 | 0.000 | 0.005 | 0.62 | 0.38 | 0.78 | 0.03 | 13.1 |
| | 14 | A | N′ | 0.468 | 0.028 | 0.011 | 0.491 | 0.002 | 0.000 | 0.48 | 0.52 | 0.78 | ** | 5.1 |
| | 15 | B | O′ | 0.160 | 0.671 | 0.019 | 0.141 | 0.000 | 0.009 | 0.33 | 0.67 | 0.79 | 0.09 | 4.8 |

The symbol “**” in Table 9 indicates that the content was below the quantitative limit of the analyzer. In this case, a peak assign to chlorine in the characteristic X-ray spectrum was observed by single-element detection of chlorine only, which results confirmed that chlorine was contained in trace amounts.

It was also confirmed that all of Examples, Comparative Examples have crystal grains with a substantially NaCl-type face-centered cubic structure.

While each of Examples 11 to 15 and Comparative Examples 11 to 15 was screwed to the tip of a tool steel bite with a fixture, wet end face cutting tests were conducted on a hollow round bar of alloy steel SCM440 with two evenly spaced grooves to measure the flank wear width of the cutting edge.

This cutting test is a process in which flank wear readily progresses and the cutting edge is prone to chipping due to intermittent machining. Since this machining requires both wear resistance and chipping resistance, the test is suitable for the evaluation of hardness and toughness.

### Cutting Test

Workpiece material: JIS SCM440
   Hollow Round Bar with Two Evenly Spaced Grooves (20 mm Wide)
(Outer diameter: Φ180, inner diameter: Φ50)
Cutting speed: 250 m/min
Depth of cut: 1.5 mm
Feed rate: 0.4 mm/rev
Number of cutting operations: 20 passes

Table 10 shows the results of the cutting test. For Comparative Examples 11 to 15, the number of cutting passes to the end of the life is shown because the tool reached the life before the number of cutting operations reached 20 passes due to chipping or flank wear (criterion of life determination: flank wear width 0.4 mm).

TABLE 10

| | | | | | Number of |
|---|---|---|---|---|---|
| | | | | | cutting |
| | | Width of | | | passes to |
| | | flank | | | reach |
| Type | | wear (mm) | Type | | lifetime |
| Examples | 11 | 0.22 | Comparative | 11 | 18 |
| | 12 | 0.23 | Examples | 12 | 17 |
| | 13 | 0.21 | | 13 | 17 |
| | 14 | 0.23 | | 14 | 16 |
| | 15 | 0.18 | | 15 | 8 |

As the results shown in Table 10 indicate that Examples 11 through 15 all exhibited low wear, no chipping, and improved both hardness and toughness, demonstrating excellent cutting performance over a long period of time.

In contrast, Comparative Examples 11 to 15 each showed a large amount of wear or chipping and reached the end of its service life in a short time.

The disclosed embodiments are in all respects illustrative only and are not restrictive. The scope of the invention is indicated by the claims, not the embodiments, and is intended to include all modifications within the gist and scope of the claims and equivalents.

### REFERENCE NUMERALS

1 Ti atom
2 anionic site (N atom)
3 anionic site (C atom)
4 cationic site (Ti, V, Zr, or Nb atom or Ti, V, Zr, Nb, Hf, or Ta atom (Hf and Ta are optional depending on composition))

1. A surface coated cutting tool comprising:
a substrate; and
a coating layer on a surface of the substrate, wherein
the coating layer comprises a complex carbonitride layer,
the complex carbonitride layer has an average thickness of 1.0 μm or more and 20.0 μm or less,
the complex carbonitride layer comprises NaCl-type face-centered cubic crystal grains each containing:
metal components Ti, V, Zr, and Nb in atomic fractions a₁, a₂, a₃, and a₄, respectively, where the total atomic fraction of the metal components in the layer is 1;
non-metallic components C and N in atomic fractions b₁ and b₂, respectively, where the total atomic fraction of the non-metallic components is 1; and
inevitable impurities, and
the atomic fractions a₁, a₂, a₃, a₄, b₁, and b₂ satisfy the following relations:
$$0.01 \leq {a}_{1} \leq 0.6 ,$$
$$0.01 \leq {a}_{2} \leq 0.6 ,$$
$$0.01 \leq {a}_{3} \leq 0.6 ,$$
$$0.01 \leq {a}_{4} \leq 0.6 ,$$
$$0.2 \leq {b}_{1} \leq 0.8 ,$$
$$and$$
$$0.2 \leq {b}_{2} \leq 0.8 ,$$
the crystal grains each have a configuration parameter S_{config} expressed by Expression 1 of 0.80R or more,
$${S}_{config} = - \frac{R}{2} [ {\sum }_{i = 1}^{n} {a}_{i} ln ( {a}_{i} ) + {\sum }_{j = 1}^{m} {b}_{j} ln ( {b}_{j} ) ] \qquad ( 1 )$$
where n=4 and m=2, ln represents the natural logarithm, and R represents the gas constant.

2. The surface coated cutting tool set forth in claim 1, wherein
the complex carbonitride layer further contains at least one metallic component selected from the group consisting of Hf and Ta in atomic fractions of a₅ and a₆, respectively, and
the atomic fractions a₅ and a₆ satisfy the following relations:
a₅<0.01, and
a₆<0.01, respectively,
the crystal grains each have a configuration parameter S_{config} expressed by Expression 1 of 0.80R or more,
where n=6 and m=2, ln represents the natural logarithm, and R represents the gas constant, with the proviso that if aᵢ (i=5 or 6) is zero (not contained), aᵢln(aᵢ)=0.

3. The surface coated cutting tool set forth in claim 1, wherein the complex carbonitride layer further contains 0.50 atomic percent or less of Cl.
